(19) United States
(12) Patent Application Publication
(10) Pub. No.: US 2003/0175425 A1
(43) Pub. Date: Sep. 18, 2003

(54) Vapor phase deposition method for metal oxide dielectric film

(76) Inventor: Toru Tatsumi, Minato-ku (JP)

Correspondence Address: SUGHRUE MION, PLLC, 2100 PENNSYLVANIA AVENUE, N.W., WASHINGTON, DC, 20037, US

(21) Appl. No.: 10/343,906

(22) PCT Filed: Aug. 8, 2001
(86) PCT No.: PCT/JP01/06819

(30) Foreign Application Priority Data
Aug. 9, 2000 (JP) 2000-241222

(51) Int. Cl. C23C 16/00

(52) U.S. Cl. 427/255.28

(57) ABSTRACT

When forming a metal oxide dielectric film having a perovskite crystal structure represented by ABO₃ on a base metal, the metal oxide dielectric film is vapor-deposited by two-stage thermal CVD using an organometallic source gas and an oxidizing gas comprising the first step of feeding a Pb organometallic source gas alone or in combination with an oxidizing gas before depositing the metal oxide dielectric film; and then the second step of feeding an organometallic gas to be a source for the metal oxide dielectric film to deposit the metal oxide dielectric film. This process can grow a film (e.g., PZT) exhibiting a reduced leak current.

### TECHNICAL FIELD

This invention relates to a process for manufacturing a semiconductor device comprising a capacitative element. In particular, it relates to a process for depositing a high-dielectric or ferroelectric film for a capacitor or gate in a semiconductor integrated circuit, using an organometallic source gas.

### BACKGROUND ART

Recently, ferroelectric memories utilizing a ferroelectric capacitor as well as dynamic random access memories (DRAMs) have been intensely studied and developed. These ferroelectric memories and DRAMs comprise a selection transistor. They uses, as a memory cell, a capacitor connected to one of the diffusion layers in the selection transistor to store information. A ferroelectric capacitor comprises a ferroelectric film made of, for example, Pb(Zr,Ti)O₃ (hereinafter, referred to as “PZT”) as a capacitor insulating film and can store nonvolatile information by polarizing the ferroelectric material. On the other hand, a high-dielectric capacitor uses a high-dielectric film made of, for example, (Ba,Sr)TiO₃ (hereinafter, referred to as “BST”) as a capacitor insulating film so that a capacitance of the capacitor can be improved and can thus miniaturize a device. When using such a ceramic material in a semiconductor device, it is vital to electrically separate the ceramic material deposited on a crystallization assisting conductive layer to be a lower electrode, as a fine capacitor.

Sol-gel, sputtering and CDV techniques have been previously described as a process for depositing a film.

In sol-gel technique, a solution of an organometallic material in an organic solvent is applied by spin coating to a wafer on which a lower electrode has been formed, and is then crystallized by annealing in oxygen. Since crystallization occurs in the solid phase in the process, a considerably higher temperature is required for crystallization. When a metal oxide dielectric film is made of PZT, a crystallization temperature for adequate high-dielectric properties is 650° C. while the crystal disadvantageously exhibits poor orientation. Furthermore, sol-gel technique is not applicable to a wafer with a large diameter and provides an inadequate step coverage to be applied in a highly integrated device.

Sputtering is a method where a sintered ceramic is used as a target; films are formed by reactive sputtering using Ar+O₂ plasma on a wafer with an electrode. Thereafter, crystallization is performed by annealing in oxygen. A target with a large diameter can be used to improve uniformity and a plasma input power can be increased to achieve an adequate deposition rate. Sputtering, however, also has a drawback that crystallization requires a higher temperature; for example, when a metal oxide dielectric film is made of PZT, a crystallization temperature is 600° C. for adequate ferroelectric properties and 650° C. for adequate high-dielectric properties. In sputtering, a film composition substantially depends on a target composition. Thus, for changing a film composition, a target must be replaced, which is disadvantageous in the light of a process efficiency.

In a CVD process, a gaseous material is fed into a vessel in which a substrate is placed, to be deposited. CVD technique gives good uniformity and a good coverage to a surface step, and is, therefore, believed to be a promising process for a ULSI. Metals as a constituent element of a ceramic may include Ba, Sr, Bi, Pb, Ti, Zr, Ta and La. Since they do not form an appropriate hydride or chloride, organometallic materials are used in a vapor growth method. These organometallic materials, however, has a lower vapor pressure and most of these materials exist in a solid or liquid state. These are, therefore, fed using a carrier gas.

Such a method, however, has a drawback that a flow rate of an organometallic material in a carrier gas cannot be quantified and the flow rate cannot be precisely controlled because the carrier gas contains the organometallic source gas at a higher pressure than a saturated vapor pressure at a temperature of a material tank and the flow rate depends not only on a flow rate of the carrier gas but also on other factors such as a surface area of the solid material and a temperature of a temperature controlled bath. Furthermore, Jpn. J. Appl. Phys, Vol. 32 (1993), p.4175 has described that in deposition of a PTO (lead titanate: PbTiO₃) using the above deposition method, a deposition temperature of the PTO is also as very high as 570° C. and orientation is insufficient.

For forming a ferroelectric memory or DRAM in the prior art, deposition processes as described above have been used. These processes, however, essentially require heating at a higher temperature of 600° C. or more in an oxygen atmosphere while orientation cannot be controlled.

In the light of a structural aspect of a semiconductor device, either of the electrodes in a ferroelectric or high-dielectric capacitor must be electrically connected to a diffusion layer in a selection transistor for operation of the capacitor. In the prior art, a DRAM generally has a capacitor structure where a polysilicon film connected to one of the diffusion layers in a selection transistor is one of the electrodes and, for example, an SiO₂ or Si₃N₄ film is formed on the surface of the polysilicon film as an insulating film. When depositing a ceramic film directly on the polysilicon surface, the polysilicon, however, oxidized because the ceramic film is made of an oxide, leading to an improper film. Thus, 1995 Symposium on VLSI Technology Digest of Technical Papers, p. 123 has described a cell structure where an upper electrode in a capacitor is connected to a diffusion layer via a local wiring of a metal such as Al. In addition, International electron devices meeting technical digest, p. 843 (1994) has described a technique where a PZT capacitor is formed on polysilicon using a TiN barrier metal. In terms of a DRAM, for example, International electron devices meeting technical digest, p. 831 (1994) has described a technique where a capacitor is formed by depositing an STO (strontium titanate: SrTiO₃) film on an RuO₂/TiN lower electrode formed on a polysilicon plug.

JP-A 11-317500 has disclosed a memory cell structure where a capacitor is connected to a diffusion layer via a plug having a laminated structure of a multilayer metal wiring and a via formed simultaneously with formation of the metal wiring, in contrast to a memory cell structure in the prior art where a capacitor is connected to a diffusion layer via, for example, a local wiring or polysilicon plug.

For solving the above problems, JP-A 2000-58525 has described a process for forming a perovskite type of metal oxide dielectric film on a lower electrode using an organometallic source gas wherein initial nuclei or an initial layer are/is formed under the first conditions and a film-formation is performed under the second conditions in which the supply quantity of the material and the like are changed from the first conditions. According to this process, a perovskite type crystal exhibiting good orientation can be formed at a temperature of about 450° C. or lower in an oxygen atmosphere. A metal oxide dielectric film can be, therefore, formed on a semiconductor substrate after forming an aluminum wiring and because of a higher capacitance, a device can be miniaturized.

On the other hand, a source voltage must be reduced for acceleration and size reduction and a ceramic capacitor insulating film must be made thinner for applying a sufficient electric field to the capacitor insulating film. However, the thinner the film is, the more significant a leak current is. Even by the process disclosed in JP-A 2000-58525, a considerable leak current may be generated under certain conditions.

In a practical process for manufacturing a semiconductor device, mask alignment must be repeated in a lithography process. After deposition of a metal oxide dielectric film such as a PZT, a film, depending on its crystallization state, may become opaque, causing irregular reflection such that an alignment mark becomes obscure, leading to difficulty in subsequent alignment.

### DISCLOSURE OF THE INVENTION

In view of the problems in the prior art, an objective of this invention is to provide a vapor growth process for a PZT film (Pb(Zr,Ti)O₃ film) with a reduced leak current. Another objective of this invention is to provide a vapor growth process for a PZT film wherein even after deposition of the PZT film, the film exhibits good flatness, thus irregular reflection is reduced and mask alignment can be smoothly conducted.

This invention provides a vapor growth process by thermal CVD for forming a metal oxide dielectric film having a perovskite type of crystal structure represented by ABO₃ on a base metal using an organometallic source gas and oxidizing gas, comprising a first step of feeding a Pb organometallic source gas alone or in combination with an oxidizing gas before depositing the metal oxide dielectric film, and thereafter, a second step of feeding an organometallic gas, which is a source for the metal oxide dielectric film, to form the metal oxide dielectric film.

This invention also provides the vapor growth process for forming a metal oxide dielectric film as described above wherein the surface of the base metal is flattened in the first step.

The base metal is preferably Pt and the metal oxide dielectric film to be grown is preferably a PZT film.

In the deposition in the second step, the first deposition conditions as the initial deposition conditions may be different from the second deposition conditions as the subsequent deposition conditions.

Specific examples may include (A) a process wherein under the first deposition conditions, using all of the organometallic source gases for the metal oxide dielectric film, the formation of initial nuclei or an initial layer having a perovskite crystal structure is performed on the lower electrode and the crystallization assisting conducting film and then under the second deposition conditions, growth of film having perovskite crystal structure is performed on the initial nuclei or the initial layer; and (B) a process wherein under the first deposition conditions, using only some of the organometallic source gases for the metal oxide dielectric film, formamtion of initial nuclei or an initial layer having a perovskite crystal structure is performed on the conducting material and under the second deposition conditions, growth of film having perovskite crystal structure is performed on the initial nuclei or the initial layer.

### BRIEF DESCRIPTION OF THE DRAWINGS

FIG. 1 schematically shows growth of a PZT when pre-feeding of a Pb source is conducted.

FIG. 2 shows an example of a feeding timing for a source gas according to this invention.

FIG. 3 shows an example of a feeding timing for a source gas according to this invention.

FIG. 4 shows an example of a feeding timing for a source gas according to this invention.

FIG. 5 shows an example of a feeding timing for a source gas according to this invention.

FIG. 6 shows an example of a feeding timing for a source gas according to this invention.

FIG. 7 is an image (photograph) of the surface of a Pt base metal film as observed by atomic force microscopy.

FIG. 8 is an image (photograph) of the surface of a Pt base metal film as observed by atomic force microscopy when a Pb source gas is fed for three seconds.

FIG. 9 is an image (photograph) of the surface of a Pt base metal film as observed by atomic force microscopy when a Pb source gas is fed for nine seconds.

FIG. 10 is a series of images (photograph) of a vapor growth process as sequentially observed by atomic force microscopy.

FIG. 11 is a series of images (photograph) of a vapor growth process subsequent to FIG. 10 as sequentially observed by atomic force microscopy.

FIG. 12 is an image (photograph) of the surface of a grown PZT film as observed by scanning electron microscopy (without pre-feeding of the Pb source).

FIG. 13 is an image (photograph) of the surface of a grown PZT film as observed by scanning electron microscopy (with pre-feeding of the Pb source for three seconds).

FIG. 14 is an image (photograph) of the surface of a grown PZT film as observed by scanning electron microscopy (with pre-feeding of the Pb source for six seconds).

FIG. 15 is an image (photograph) of the surface of a grown PZT film as observed by scanning electron microscopy (with pre-feeding of the Pb source for nine seconds).

FIG. 16 shows I-V properties of a PZT film formed according to this invention.

FIG. 17 shows I-V properties of a PZT film formed according to a conventional method.

FIG. 18 shows hysteresis properties of a PZT film formed according to this invention.

FIG. 19 shows an example of a process for manufacturing a device to which this invention is applied.

FIG. 20 shows an example of a process for manufacturing a device to which this invention is applied.

FIG. 21 shows an example of a process for manufacturing a device to which this invention is applied.

FIG. 22 shows an example of a process for manufacturing a device to which this invention is applied.

FIG. 23 schematically shows growth of a PZT according to a conventional method.

In these figures, 1 is a base Pt film; 2 is an alloy layer of Pt and Pb; 3 is a PTO crystal nucleus; 4 is a PZT polycrystal; 11 is a base Pt film; 12 is a PTO crystal nucleus; 13 is a PZT polycrystal; and 14 is a grain boundary.

### BEST MODE FOR CARRYING OUT THE INVENTION

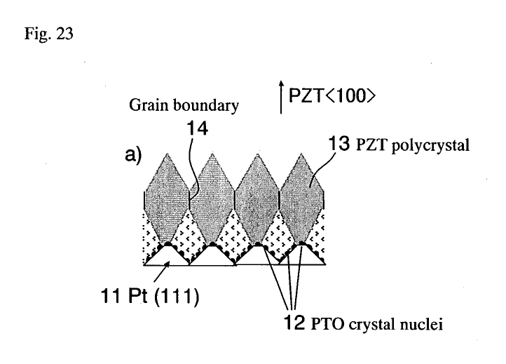

FIG. 23 schematically shows growth of a PZT polycrystal 13 on a base Pt film as a base metal film in a deposition process at a low temperature by MOCVD according to the prior art. There will be herein described a case where PTO (lead titanate: PbTiO₃) crystal nuclei 12 are formed under the first deposition conditions and then a PZT is deposited under the second deposition conditions as described in JP-A 2000-58526.

According to our investigation, it is important to improve crystallinity of a base metal by sputtering the base metal at a higher substrate temperature of generally 300 to 400° C. for providing a PZT with good crystallinity by thermal CVD (MOCVD) at a lower substrate temperature (e.g., 450° C. or less). A polycrystal metal formed by sputtering at a higher temperature generally has a rough surface such that the center of the polycrystal grain is convex while the grain boundary is concave. In this connection, Pt may be deposited at room temperature to provide a film having a surface with good flatness, but its crystallinity is inadequate to deposit on the film a PZT film with good crystallinity by thermal MOCVD at a low temperature. When forming PTO crystal nuclei 12 on such a rough surface of a base metal, the number of perovskite nuclei is larger than that of polycrystal grain of the base metal as shown in FIG. 23. Most of the perovskite nuclei has a (100) orientation to the surface. Thus, during subsequent PZT deposition, growth of a PZT is initiated such that a direction perpendicular to its surface is (100).

However, when the surface of the base metal is irregular, only grains from nuclei having a (100) orientation to a direction perpendicular to the surface of the substrate can significantly grow. Thus, grains having tilting surface to the substrate, that is, grains that do not have (100) orientation in a direction perpendicular to the substrate, are eliminated by interference between grains during the initial stage of deposition. As a result, when the base metal has a rough surface, the PZT polycrystal 13 grown on the surface has a larger grain size, leading to a larger facet formed in the surface and thus a rougher PZT surface. It reduces a distance between the surface and the base metal, leading to a problem of a larger leak current. The thinner the film is, the more significant the problem is. Difficulty in distinguishing an alignment mark through a PZT film thus formed is due to larger irregular reflection on the rougher surface.

According to this invention, a Pb source gas is introduced without feeding other organometallic source gases before depositing a metal oxide dielectric film. Pb source gas is decomposed on a base metal surface and reacts with the base metal. During a subsequent step of depositing a metal oxide dielectric film by feeding an organometallic gas as a source, a metal oxide dielectric film with a smaller grain size and reduced surface roughness can be formed. Since the Pb source is fed before the other organometallic sources in the first step, the procedure is sometimes referred to as “Pb pre-feeding” in the following description or the drawings.

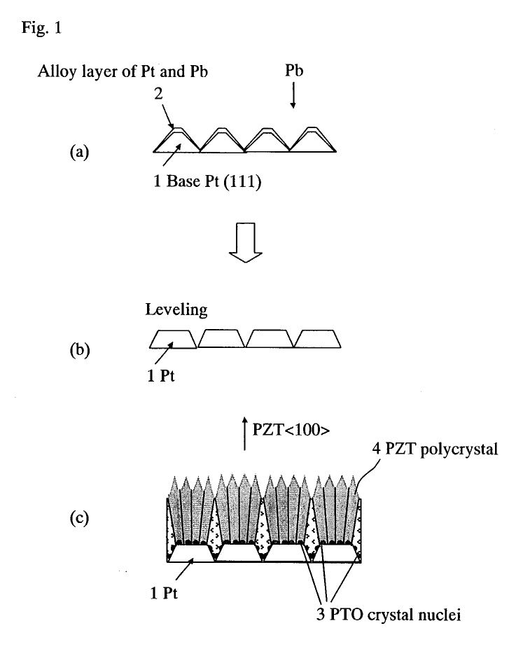

Formation of a PZT polycrystal on a Pt film (a base metal film), as similar to JP-A 2000-58526, will be schematically described with reference to FIG. 1, for an exemplary case where PTO crystal (lead titanate: PbTiO₃) nuclei are formed under the first deposition conditions and then a PZT is deposited under the second deposition conditions. FIG. 1(a) shows feeding of a Pb source gas to the surface of the Pt film in the first step. When the Pb source is fed on the surface of the Pt base film 1, we think Pb is probably formed on the base metal surface to form an alloy layer 2 of Pt and Pb on the outermost surface. As a result, mobility of atoms in the base metal surface would be increased, resulting in reconstruction of the surface such that flatness of the base metal surface is improved as shown in FIG. 1(b).

When PTO crystal nuclei 3 are formed on the flattened surface of the base metal, as FIG. 1(c) shows, the density of nuclei of the (100) orientation in the direction perpendicular to the substrate increases, and as s result, the flatness of the surface of the PTZ film is improved.

A base metal herein is preferably Pt, but other metals such as Ir, Os and Ru may be similarly leveled by feeding a Pb source. The base metal may be a monolayer or multilayer film. When applying this invention to formation of a capacitor film, a multilayer film is often formed for various reasons in a practical semiconductor device. In either case, any of the above metals can be used as a base metal on which a metal oxide dielectric film is formed. When forming a multilayer structure using Pt as a base metal, a lower layer thereof may be appropriately selected. In a Pt/TiN/Ti structure where TiN is deposited on Ti, the TiN layer acts as a barrier for preventing diffusion of Ti. Furthermore, the TiN has a crystal structure having a highly oriented to (111), and therefore the Pt is also oriented to (111). Thus, when using a vapor growth process according to this invention, a metal oxide dielectric film also tends to be oriented and show good crystallinity. A Pt/TiN/Ti/W structure where a W layer is further provide under the layers of the above structure is more preferable.

A particularly preferable Pb source is, but not limited to, lead bis(dipivaloylmethanate) (Pb(DPM)₂).

During feeding a Pb source gas alone or in combination with an oxidizing gas, i.e., during the first step, a temperature of a base metal (i.e., a substrate temperature) is generally 350 to 700° C., preferably 390° C. or higher and 600° C. or lower. According to the conventional vapor growth process, although a higher temperature leads to more intense polarization and thus provides a larger capacity, a leak current tends to be increased. On the other hand, according to this invention, a leak current is effectively reduced. When forming a metal oxide dielectric film on a substrate provided with an aluminum wiring in a practical semiconductor device, the first step is preferably conducted at a temperature of 450° C. or lower, taking heat resistance of the aluminum wiring into account.

Even when a duration of the first step is very short, feeding a Pb source gas alone or in combination with an oxidizing gas can correspondingly reduce irregularity in the surface of a metal oxide dielectric film deposited. However, since a excessively longer duration of the first step may cause generation of a PbO film, the duration and the conditions are restricted within the range where a PbO film is not formed. A period until a PbO film is formed may depend on the conditions, but can be experimentally determined using X-ray diffraction. Generally, the period is 60 sec or less, preferably 3 to 20 sec.

A total pressure during feeding a Pb source gas in the first step is 10⁻¹ Torr or less, particularly 10⁻² Torr or less.

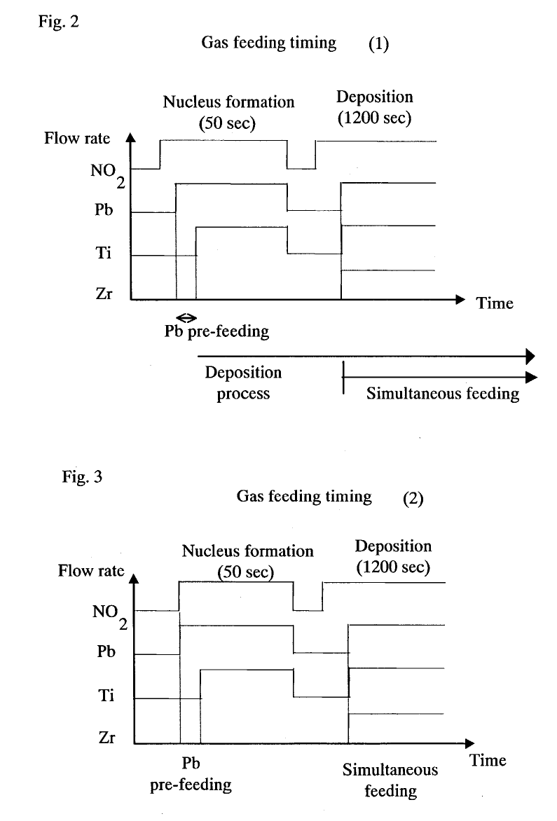

A timing of feeding a Pb source gas in the first step will be described for a representative example of PZT formation with reference to FIGS. 2 to 6.

FIG. 2 shows typical feeding timings for source gases for PZT deposition. According to this growth process, into a vessel charged with NO₂ as an oxidizing gas is fed a Pb source gas and the system is maintained in the state for a predetermined period, during which a base metal is leveled. Then, introduction of a Ti source gas is started to initiate the second step of depositing a PZT in succession. In this example, initial PTO nuclei are formed under the first conditions without feeding a Zr source, and then a PZT is deposited by feeding all the sources including the Zr source under the second conditions.

In an example of gas feeding timing shown in FIG. 3, in the first step, NO₂ and a Pb source gas are simultaneously fed and then the system is maintained in the state for a predetermined period.

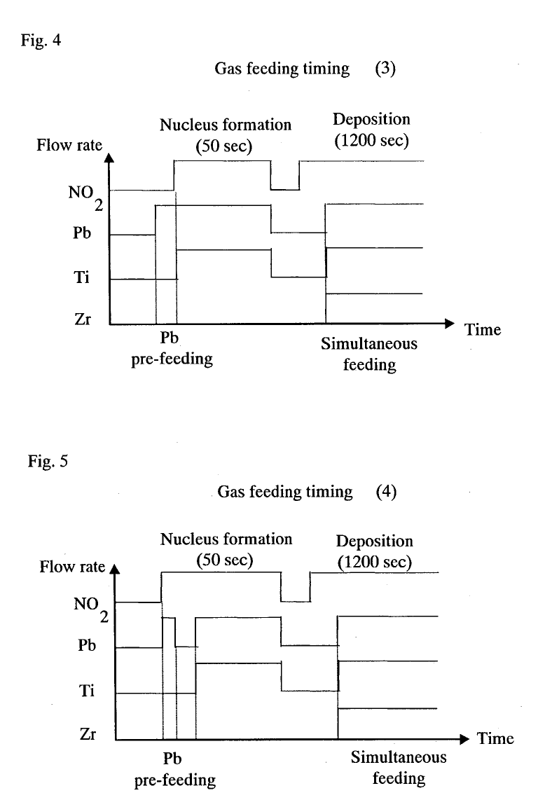

In an example of gas feeding timing shown in FIG. 4, in the first step, a Pb source gas is fed alone and then the system is maintained in the state for a predetermined period.

In an example of gas feeding timing shown in FIG. 5, in the first step, NO₂ and a Pb source gas are simultaneously fed, the system is maintained in the state for a predetermined period, feeding of the Pb source gas is discontinued and then the Pb source and a Ti source are fed to initiate deposition.

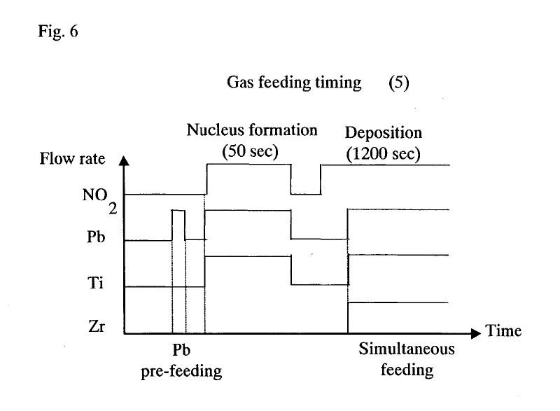

In an example of gas feeding timing shown in FIG. 6, in the first step, a Pb source gas is fed alone, the system is maintained in the state for a predetermined period, feeding of the Pb source gas is discontinued and then NO₂, the Pb source and a Ti source are fed to initiate deposition.

Examples of a metal oxide dielectric represented by ABO₃ having a perovskite type crystal structure deposited by a process according to this invention include, besides a PZT, STO [SrTiO₃], BTO [BaTiO₃], BST [(Ba,Sr)TiO₃], PTO [PbTiO₃], PLT [(Pb,La)TiO₃], PLZT [(Pb,La)(Zr,Ti)O₃], PNbT [(Pb,Nb)TiO₃], PNbZT [(Pb,Nb)(Zr,Ti)O₃], and metal oxides in which Zr of the above Zr-containing oxide is replaced with at least one of Hf, Mn and Ni.

Specifically, in this invention, a metal oxide dielectric film without Pb as an A element may be deposited on a leveled base metal by Pb pre-feeding. However, a metal oxide dielectric film containing Pb as an A element is preferable because there is no need to consider the problem of contamination with Pb. Particularly preferable metal oxides are PZT, PTO, PLT, PLZT, PNbT, PNbZT and any of those containing Zr in which Zr is replaced with at least one of Hf, Mn and Ni.

In the second deposition step, a metal oxide dielectric film can be deposited by any process. However, preferred is a process where the first deposition conditions during the initial deposition are different from the second deposition conditions during the subsequent deposition as illustrated above. Specifically, in contrast with a growth process according to the prior art where a film is deposited on a base metal under constant conditions, it is preferably that initial nuclei or an initial layer having a perovskite type crystal structure is first deposited under the first deposition conditions and then a film having a perovskite type crystal structure is grown on the initial nuclei or the initial layer under the second deposition conditions, i.e., the optimal conditions for each process can be selected. Deposition under such conditions may provide a film formed exhibiting improved orientation, crystallinity and inversion fatigue. The term “initial nuclei” as used herein refers to the state where crystal nuclei exist as islands. The term “initial layer” as used herein refers to a state where the initial nuclei gather to form a continuous layer. In either state, good crystal nuclei are contained if formed sunder appropriate conditions.

Specific examples of such a deposition process may include (a) a process wherein under the first deposition conditions, all of the organometallic source gases for the metal oxide dielectric are used to form initial nuclei or an initial layer having a perovskite crystal structure on the conducting material and then under the second deposition conditions, a further film having perovskite crystal structure is grown on the initial nuclei or the initial layer; and (b) a process wherein under the first deposition conditions, only some of the organometallic source gases for the metal oxide dielectric are used to form initial nuclei or an initial layer having a perovskite crystal structure on the conducting material and under the second deposition conditions, a further film having perovskite crystal structure is grown on the initial nuclei or the initial layer. Both of these processes have been described in JP-A 2000-58525.

### EXAMPLES

This invention will be more specifically described with reference to Examples.

On a 6 inch silicon wafer as a substrate was formed a base metal layer having a Pt (100 nm)/SiO₂ structure by high-temperature sputtering at 300° C. Source gases were Pb(DPM)₂ as a Pb source, Zr(OtBu)₄ as a Zr source, Ti(OiPr)₄ as a Ti source and NO₂ as an oxidizing agent. Each gas flow rate was controlled by a mass flow controller without using a carrier gas. A pressure during growth was 5×10⁻³ Torr (6.6 Pa). A PZT was deposited by first forming island PTO nuclei (initial nuclei) with a diameter of 3 to 5 nm at a substrate temperature of 430° C. under the first conditions and then continuing deposition under the second conditions. An upper electrode was Ir/IrO₂. After forming the upper electrode, recovery annealing was conducted at 450° C. for 10 min.

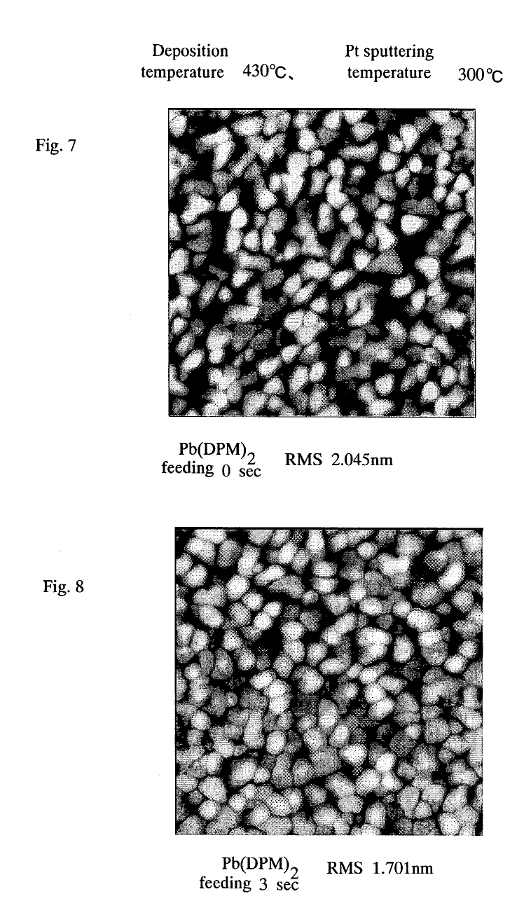

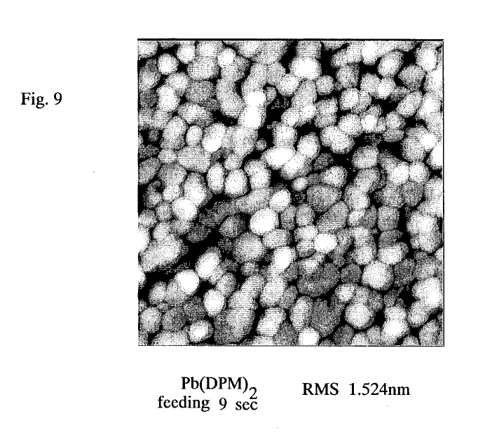

First, Pb(DPM)₂ and NO₂ were fed to the Pt base metal film. Flatness of the Pt surface was observed by atomic force microscopy (AFM) while varying a feeding time. The results are shown in FIGS. 7 to 9. FIG. 7 shows the surface of the Pt base metal used as it is, before the first step. FIGS. 8 and 9 show the surface after Pb pre-feeding (i.e., the first step) for 3 and 9 sec, respectively. Average surface roughnesses (RMS) were 2.045 nm, 1.701 nm and 1.524 nm in FIGS. 7, 8 and 9, respectively, indicating that the surface of the Pt base metal was actually leveled.

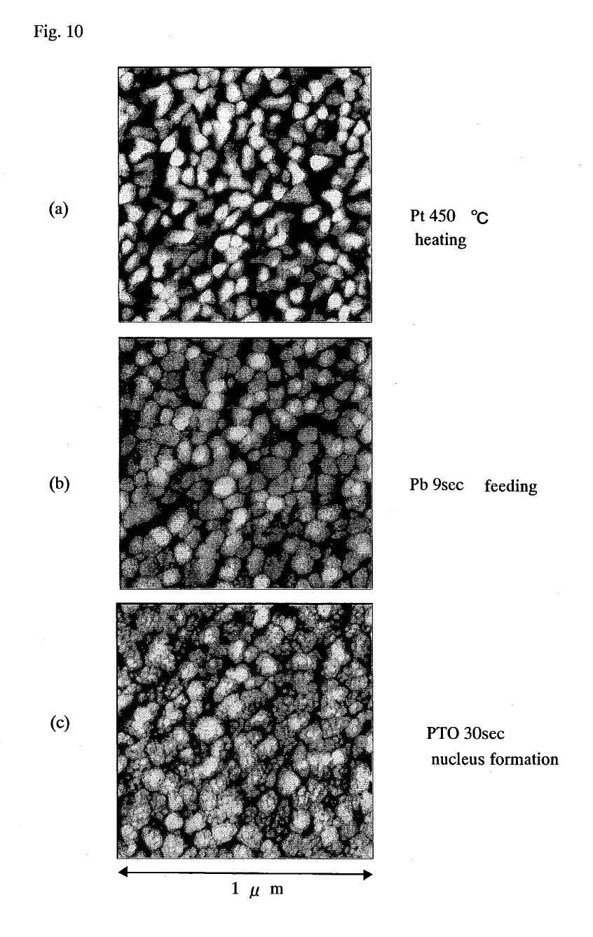

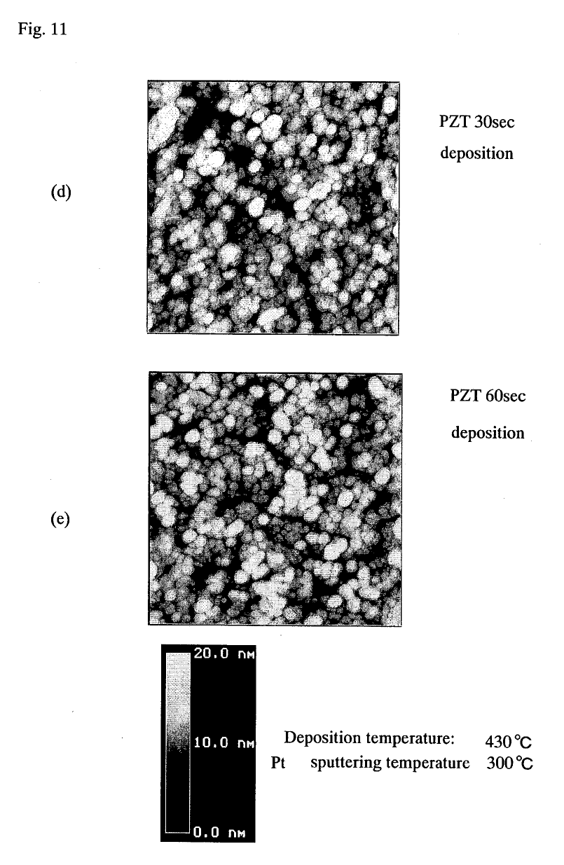

FIGS. 10 and 11 show observation of a deposition process for a PZT by atomic force microscopy in sequence. Specifically, FIG. 10(a) shows a Pt surface when it was heated at 450° C. The surface was leveled after Pb pre-feeding for 9 sec as shown in FIG. 10(b). After forming PTO initial nuclei for 30 sec, very fine nuclei were observed as shown in FIG. 10(c). After deposition of the PZT for 30 sec (FIG. 11(d)) and for 60 sec (FIG. 11(e)), formation of PZT polycrystals with a small grain size was observed while flatness of the surface was maintained.

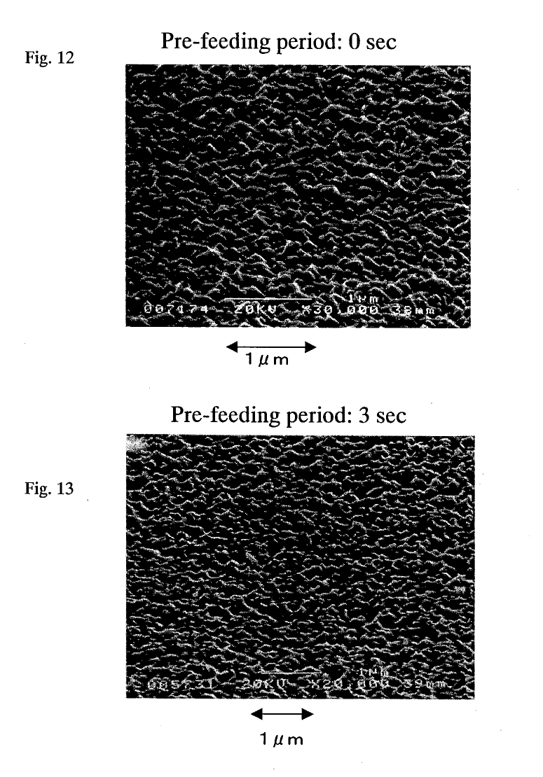

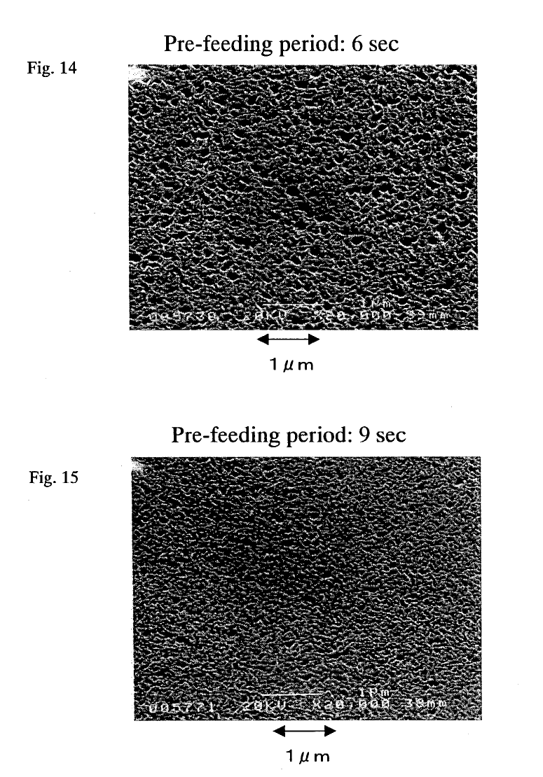

FIGS. 12 to 15 show the surface after depositing the PZT film to 200 nm by scanning electron microscopy (SEM), in which Pb pre-feeding times were 0 sec (without pre-feeding), 3 sec, 6 sec and 9 sec, respectively. It can be clearly observed that a longer Pb pre-feeding to the base metal results in smaller irregularity in the surface of the PZT deposited on the metal.

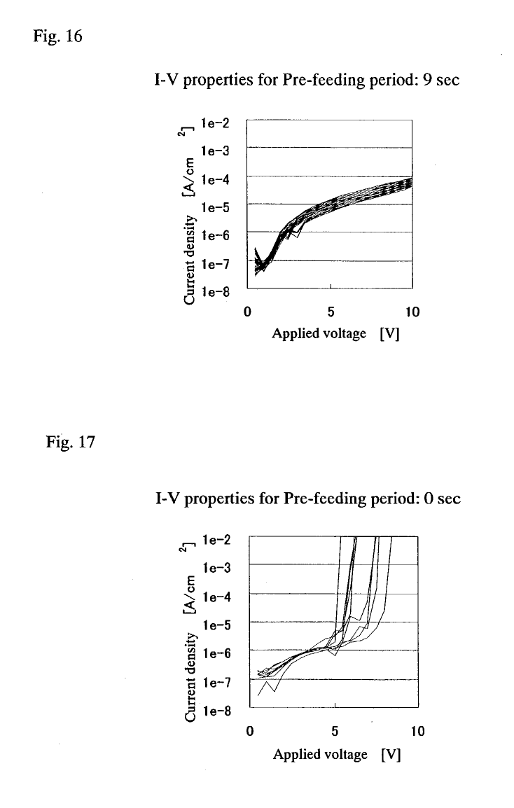

IV properties when Pb pre-feeding was conducted for 9 sec in deposition of a PZT film to 250 nm, shown in FIG. 16 indicates that a leak current was as good as 10⁻⁴ A/cm² or less at 10 V. In contrast, IV properties when a PZT film was deposited to 250 nm without Pb pre-feeding, shown in FIG. 17 indicates that a current sharply increased in the range of 5 to 8 V. From these results, it has been confirmed that Pb pre-feeding can produce a definite improvement in a leak current.

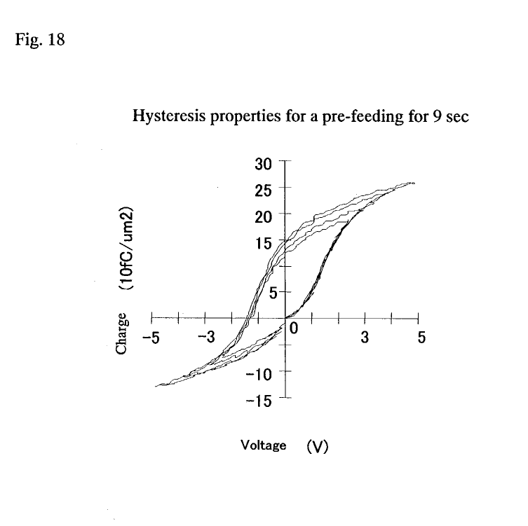

As shown in FIG. 18, a capacitor after Pb pre-feeding for 9 sec exhibited an adequate polarization value (2Pr value) and good hysteresis properties.

In terms of flatness of the PZT surface after deposition to 250 nm, an RMS value was 12.3 nm without pre-feeding of the Pb source, while it was 7.6 nm when pre-feeding of the Pb source was conducted for 9 sec.

### Device Production Example 1

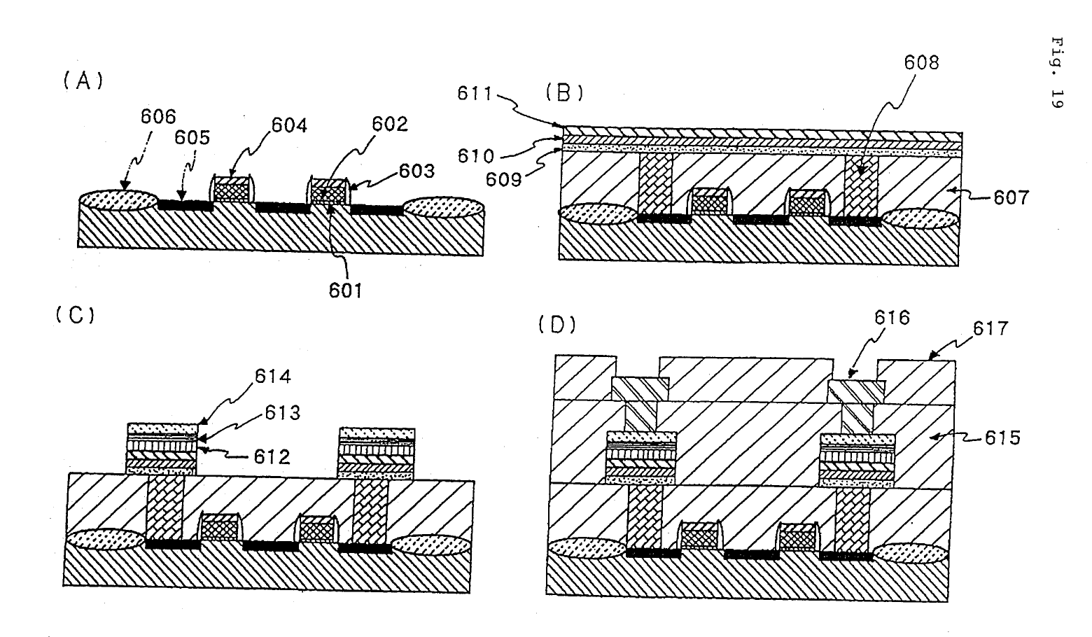

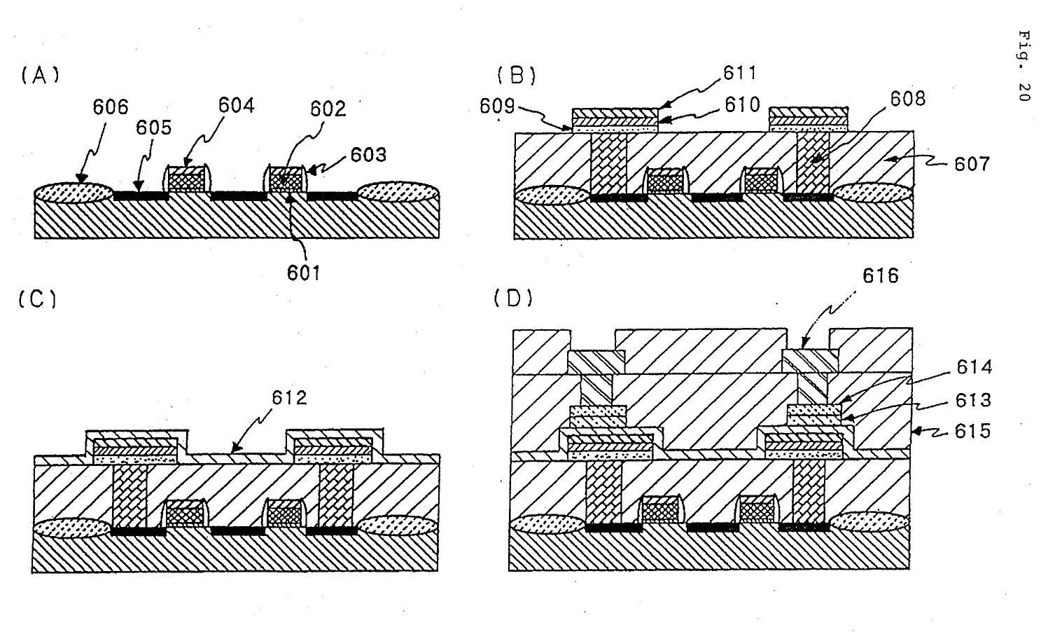

With reference to FIG. 19, there will be described Device Production Example 1, in which a memory cell was produced using a vapor growth process according to this invention. On a silicon substrate was formed an oxide film by wet oxidation. After ion-implanting of dopants such as boron and phosphorous, n-type and p-type wells were formed. Then, a gate and a diffusion layer were formed as follows. First, a gate oxide film 601 was formed by wet oxidation, and a polysilicon film 602 to be a gate was deposited and etched. On the polysilicon film was deposited a silicon oxide film, which was then etched to form a side-wall oxide film 603. Then, dopants such as boron and arsenic were ion-implanted to form an n-type and a p-type diffusion layers. On the surface was deposited a Ti film, which was then reacted with silicon. Unreacted Ti was etched off to form Ti silicide layers in a gate 604 and a diffusion layer 605. By the above process, an n-type and a p-type MOS transistors which were separated by a isolation oxide film 606 from each other were formed on the silicon substrate as shown in FIG. 19(A).

Then, a contact and a lower electrode were formed as shown in FIG. 19(B). First, on a substrate was deposited a silicon oxide film or a silicon oxide film containing dopants such as boron (BPSG) as the first interlayer insulating film 607, which was then leveled by CMP. Then, contact holes were opened by etching, dopants were implanted into each of the n-type and the p-type diffusion layers, and the product was heated at 750° C. for 10 sec. Then, Ti and TiN as a barrier metal were deposited. On the metal layers was deposited tungsten by CVD, and a tungsten plug 608 was formed by CMP. The tungsten plug may be formed by etching back of tungsten after CVD. On the surface were sequentially formed a Ti film 609 and a TiN film 610 as capacitor lower electrode layers, on which a Pt film 611 was then deposited to 100 nm.

Then, a ferroelectric capacitor was formed as shown in FIG. 19(C). A PZT was formed to 100 nm using a process according to this invention. Sources materials were lead bis(dipivaloylmethanate) (Pb(DPM)₂), titanium isopropoxide (Ti(OiPr)₄), zirconium butoxide (Zr(OtBu)₄) and an oxidizing agent was NO₂.

NO₂ was fed at a flow rate of 3.0 SCCM at a substrate temperature of 430° C., then Pb(DPM)₂ was fed at a flow rate of 0.2 SCCM for 9 sec. Ti(OiPr)₄ was then fed to initiate deposition, and deposition was continued for 30 sec under the conditions of a Pb(DPM)₂ flow rate of 0.2 SCCM, a Ti(OiPr)₄ flow rate of 0.25 SCCM and an NO₂ flow rate of 3.0 SCCM. Then, after changing the deposition conditions to a Pb(DPM)₂ flow rate of 0.25 SCCM, a Zr(OtBu)₄ flow rate of 0.225 SCCM, a Ti(OiPr)₄ flow rate of 0.2 SCCM and an NO₂ flow rate of 3.0 SCCM, deposition was continued for 600 sec to form a PZT metal oxide dielectric film 612.

The total gas pressure in the vacuum chamber during growth was 5×10⁻³ Torr, and a grown film thickness was 100 nm. An IrO₂ film 613 and an Ir film 614 were deposited by sputtering, and a capacitor upper electrode layer was formed. The capacitor upper electrode layer, a metal oxide dielectric film and a capacitor lower electrode layer were patterned by dry etching to provide PZT capacitors.

On the surface was formed a capacitor upper electrode as shown in FIG. 19(D). After forming a silicon oxide film as the second interlayer insulating film 615 by plasma CVD, a capacitor upper contact and a plate wiring contact were opened by etching. On the surface were sequentially deposited WSi, TiN, AlCu and TiN as the second metal wiring 616, which was then processed by etching. On the surface were formed a silicon oxide film and an SiON film as a passivation film 617. Then a wiring pad was opened for evaluation of electric properties.

FIG. 19 showed a process for separating a capacitor by dry etching after forming the capacitor lower electrode, the PZT film and the IrO₂/Ir capacitor upper electrode. However, the capacitor may be formed by separating the capacitor lower electrode, i.e., the Pt/TiN/Ti by dry etching, depositing the PZT, forming the IrO₂/Ir upper electrode and separating the upper electrode as shown in FIG. 20. Using the latter process, films to be dry etched may be thinner and thus a finer pattern can be formed. Furthermore, since the side of the PZT is not exposed to plasma during dry etching, no defects are introduced into the PZT film. Electric properties for the capacitors produced by the processes shown in FIGS. 19 and 20 were as follows.

Five thousand of 1-μm square PZT capacitors were parallel-connected and were determined for their properties. A difference between inversion charge and non-inversion charge was 20 μC/cm² or more, indicating good dielectric properties. Fatigue properties and retention properties were also good. A transistor with a gate length of 0.26 μm were evaluated for its properties. For both p-type and n-type transistors, variation of a threshold Vt was as good as within 10% over the entire surface of the wafer. A resistance of a 0.4 μm square capacitor lower contact was determined using a contact-chain method to give a good result that a resistance per a contact was 10 Ωcm or less. Furthermore, the PZT film deposited had improved flatness so that irregular reflection was not generated and mask alignment could be precisely conducted.

### Device Production Example 2

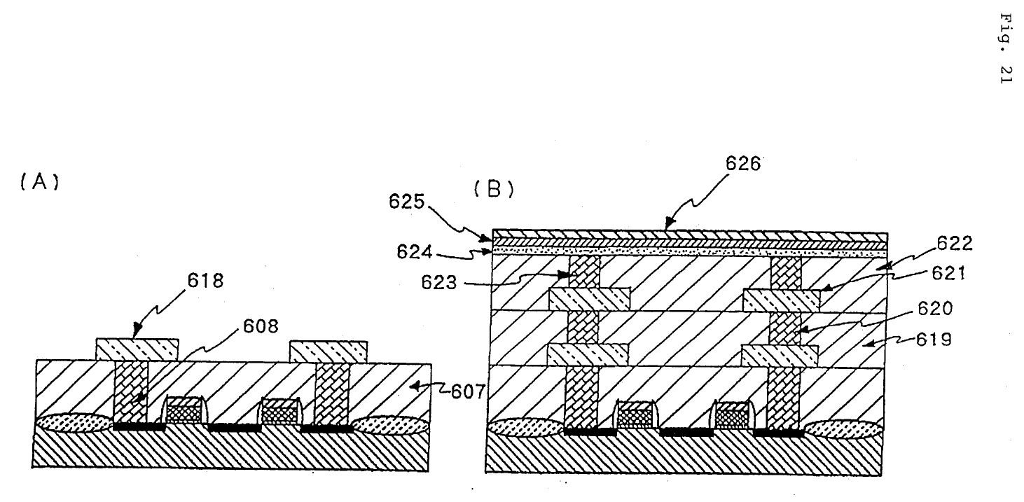

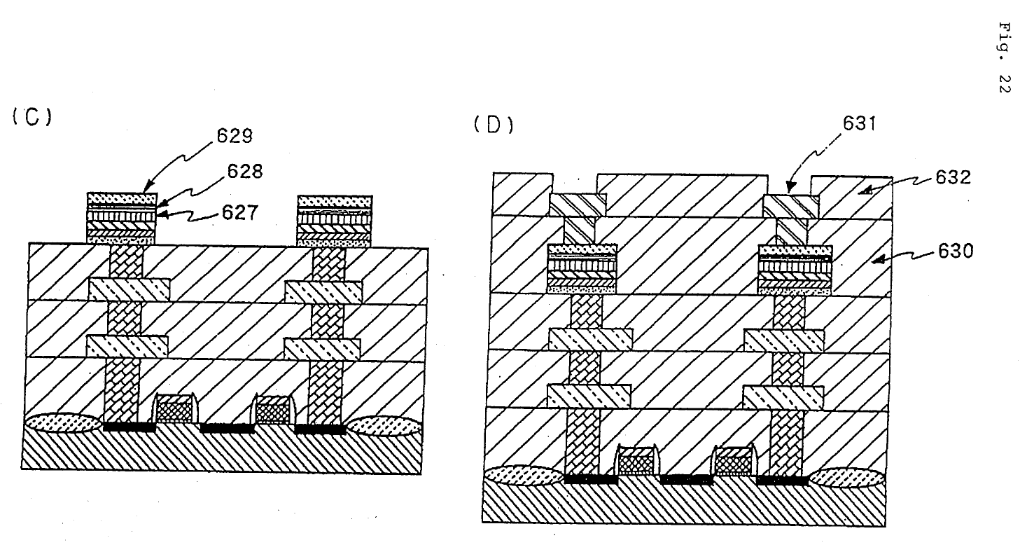

The second process for producing a memory cell in accordance with an embodiment of this invention will be described with reference to FIG. 21. The process was conducted in the same manner as described in the first embodiment for a memory cell until the formation of a tungsten plug. Then, on the surface were deposited Ti and TiN. An AlCu film was deposited by sputtering and the first aluminum wiring 618 was formed by dry etching. Thus, the first aluminum wiring was formed on an n-type and a p-type MOS transistors as shown in FIG. 21(A).

Then, a via and the second aluminum wiring were formed as shown in FIG. 21(B). First, on a substrate was deposited a silicon oxide film or a silicon oxide film containing dopants such as boron (BPSG) as the second interlayer insulating film 619, which was then leveled by CMP. Then, after opening a via hole by etching, Ti and TiN were deposited as a barrier metal. On the metal layers was deposited tungsten by CVD, and a tungsten plug 620 was formed by CMP. The tungsten plug may be formed by etching back of tungsten after CVD. Ti and TiN films were formed on the surface by sputtering, the second aluminum wiring 621 was formed by dry etching, and then a silicon oxide film or a silicon oxide film containing dopants such as boron (BPSG) was deposited as the third interlayer insulating film 622, which was then leveled by CMP. After opening a via hole by etching, Ti and TiN were deposited as a barrier metal. On the metal layers was deposited tungsten by CVD, and a tungsten plug 623 was formed by CMP. The tungsten plug may be formed by etching back of tungsten after CVD. The process of forming an aluminum wiring, an interlayer film and a via hole can be repeated to a desired number of wiring layers. On the last tungsten plug were sequentially deposited by sputtering a Ti film 624 and a TiN film 625, on which was then deposited a Pt film 626 to 100 nm to form a capacitor lower electrode.

Then, a ferroelectric capacitor was formed as shown in FIG. 22(C). A PZT was formed to 100 nm using a process according to this invention. Sources materials were lead bis(dipivaloylmethanate) (Pb(DPM)₂), titanium isopropoxide (Ti(OiPr)₄), zirconium butoxide (Zr(OtBu)₄) and an oxidizing agent was NO₂.

NO₂ was fed at a flow rate of 3.0 SCCM at a substrate temperature of 430° C., then Pb(DPM)₂ was fed at a flow rate of 0.2 SCCM for 9 sec. Ti(OiPr)₄ was then fed to initiate deposition, and deposition was continued for 40 sec under the conditions of a Pb(DPM)₂ flow rate of 0.2 SCCM, a Ti(OiPr)₄ flow rate of 0.25 SCCM and an NO₂ flow rate of 3.0 SCCM. Then, after changing the deposition conditions to a Pb(DPM)₂ flow rate of 0.25 SCCM, a Zr(OtBu)₄ flow rate of 0.225 SCCM, a Ti(OiPr)₄) flow rate of 0.2 SCCM and an NO₂ flow rate of 3.0 SCCM, deposition was continued for 600 sec to form a PZT metal oxide dielectric film 627.

The total gas pressure in the vacuum chamber during growth was 5×10⁻³ Torr, and a grown film thickness was 100 nm. An IrO₂ film 628 and an Ir film 629 were deposited by sputtering, and a capacitor upper electrode layer was formed. The capacitor upper electrode layer, a metal oxide dielectric film and a capacitor lower electrode layer were patterned by dry etching to provide PZT capacitors.

On the surface was formed an upper electrode as shown in FIG. 22(D). After forming a silicon oxide film as the fourth interlayer insulating film 630 by plasma CVD, a capacitor upper contact and a plate wiring contact were opened by etching. On the surface were sequentially deposited WSi, TiN, AlCu and TiN as the third metal wiring 631, which was then processed by etching. On the surface were formed a silicon oxide film and an SiON film as a passivation film 632. Then a wiring pad was opened for evaluation of electric properties.

When an aluminum wiring is formed in an underlying layer, the capacitor may be also formed by separating the capacitor lower electrode, i.e., the Pt/TiN/Ti by dry etching, depositing the PZT, depositing the IrO₂/Ir upper electrodelayer and forming the upper layer as shown in FIG. 20. Using the latter process, films to be dry etched may be thinner and thus a finer pattern can be formed. Furthermore, since the side of the PZT is not exposed to plasma during dry etching, no defects are introduced into the PZT film.

The memory cell thus produced in Device Production Example 2 was evaluated for its electric properties as described for the memory cell produced in Device Production Example 1.

As a result, a difference between inversion charge and non-inversion charge was 10 μC/cm² or more, indicating good dielectric properties. Fatigue properties and retention properties were also good. A leak current was as good as 10⁻⁴ A/cm² or less at 10 V. A transistor with a gate length of 0.26 μm were evaluated for its properties. For both p-type and n-type transistors, variation of a threshold Vt was as good as within 10% over the entire surface of the wafer. A resistance of a 0.4 μm square capacitor lower contact was determined using a contact chain to give a good result that a resistance per a contact was 10 Ωcm or less. Furthermore, the PZT film deposited had improved flatness so that irregular reflection was not generated and mask alignment could be precisely conducted.

There have been described Device Production Examples 1 and 2 in which tungsten was used as a contact, but a polysilicon contact also exhibited improvement in ferroelectric capacitor properties, transistor properties and a contact resistance.

### INDUSTRIAL APPLICABILITY

As described above, this invention can provide a vapor growth process for forming a PZT film (Pb(Zr,Ti)O₃ film) with a reduced leak current. Furthermore, this invention can provide a vapor growth process for forming a PZT film whereby the film has good transparency and mask alignment can be satisfactorily conducted even after deposition of the PZT film.

What is claimed is:

1. A vapor growth process by thermal CVD for forming a metal oxide dielectric film having a perovskite type of crystal structure represented by ABO₃ on a base metal using an organometallic source gas and oxidizing gas, comprising
a first step of feeding a Pb organometallic source gas alone or in combination with an oxidizing gas before depositing the metal oxide dielectric film; and thereafter,
a the second step of feeding an organometallic gas, which is a source for the metal oxide dielectric film, to form the metal oxide dielectric film.

2. (after amendment) A vapor growth process for forming a metal oxide dielectric film as claimed in claim 1 wherein PbO is not precipitated during the first step.

3. (after amendment) A vapor growth process for forming a metal oxide dielectric film as claimed in claim 1 wherein both A element and B element sources are fed throughout the second step.

4. (after amendment) A vapor growth process for forming a metal oxide dielectric film as claimed in any of claims 1 to 3 wherein the surface of the base metal is flattened in the first step.

5. (after amendment) A vapor growth process for forming a metal oxide dielectric film as claimed in any of claims 1 to 4 wherein the base metal is Pt.

6. (after amendment) A vapor growth process for forming a metal oxide dielectric film as claimed in any of claims 1 to 5 wherein the metal oxide dielectric film to be grown is a PZT film.

7. (after amendment) A vapor growth process for forming a metal oxide dielectric film as claimed in any of claims 1 to 6 wherein, in the second step, the first deposition conditions as the initial deposition conditions are different from the second deposition conditions as the subsequent deposition conditions.

8. (added) A vapor growth process for forming a metal oxide dielectric film as claimed in claim 7 wherein under the first deposition conditions, using all of the organometallic source gases for the metal oxide dielectric film, formation of initial nuclei or an initial layer having a perovskite crystal structure on the base metal film is performed, and then under the second deposition conditions, growth of film having perovskite crystal structure on the initial nuclei or the initial layer is performed.

9. (added) A vapor growth process for forming a metal oxide dielectric film as claimed in claim 7 wherein under the first deposition conditions, using only some of the organometallic source gases for the metal oxide dielectric film, formation of initial nuclei or an initial layer having a perovskite crystal structure on the base metal film is performed, and under the second deposition conditions, growth of film having perovskite crystal structure on the initial nuclei or the initial layer is performed.
